(19) United States
(12) Patent Application Publication
(10) Pub. No.: US 2021/0263096 A1
(43) Pub. Date: Aug. 26, 2021

(54) SYSTEM FOR CALIBRATING A MEASUREMENT ANTENNA OF AN RF TEST ARRANGEMENT

(71) Applicant: Rohde & Schwarz GmbH & Co. KG, Munich (DE)

(72) Inventors: Markus HERBRIG, Grafing (DE); Henry GROPP, Munich (DE); Larisa SERDAREVIC, Munich (DE)

(21) Appl. No.: 16/798,304

(22) Filed: Feb. 22, 2020

(51) Int. Cl. G01R 31/28; G01R 31/319; H04B 17/10

(52) U.S. Cl. CPC G01R 31/2822; H04B 17/102; G01R 31/3191

(57) ABSTRACT

The invention relates to a system for calibrating a measurement antenna of an RF test arrangement, comprising: a calibration antenna, and a fixture, wherein the calibration antenna is mounted to the fixture, and wherein the fixture comprises an aperture for removably mounting the fixture on the measurement antenna, wherein the calibration antenna is arranged at a fixed distance from the measurement antenna if the fixture is mounted on the measurement antenna.

### TECHNICAL FIELD OF THE INVENTION

The invention relates to a system and a method for calibrating a measurement antenna of an RF test arrangement. The invention further relates to a test method for an electronic device, in particular a DUT, and an RF test arrangement.

### BACKGROUND OF THE INVENTION

Many measurement devices undergo testing at first manufacture or later during their life cycle. Devices, which are tested in such a way, are referred to as devices under test (DUT).

Measurement devices for performing radio frequency (RF) measurements often undergo RF performance tests. These tests comprise over the air (OTA) measurements that are performed in shielded chambers or boxes to prevent interference with other signals. For this purpose, RF measurement antennas are arranged in the chambers. Such measurement antennas must be calibrated to provide accurate results.

To calibrate such measurement antennas it is known to perform path loss calibration measurements, e.g. to determine the power radiated by said antennas.

Such path loss calibration measurements can be performed using calibration antennas. However, it is difficult to align the calibration antennas accurately to the measurement antennas in the chamber. Especially when different measurement antennas in one chamber need to be calibrated, the alignment should be identically for each antenna, which is difficult to achieve.

Alternatively, it is known to place a reference device, also called “golden device”, with well known characteristic, in the test chamber and to compare a test measurements with the golden device to a measurements with the DUT. However, using such a golden device can be time consuming and can lead to additional costs for providing a suitable golden device.

Document US 2019/0327694 A1 discloses an alternative method for RF gain calibration and/or characterization of one or more RF transmitter and/or receiver. Thereby, measurements, e.g. temperature measurements, of a chain of RF components of a device, such as an automotive sensor, can be used to calibrate the gain of said components via a gain control and a configuration circuitry of the device. Hence, this approach requires a specially designed device.

Thus, it is an objective to provide a an improved system and an improved method for calibrating a measurement antenna of an RF test arrangement, an improved test method for an electronic device and an improved RF test arrangement, which avoid the above-mentioned disadvantages. In particular, it is an objective to provide a system and a method for calibrating a measurement antenna quickly and accurately.

### SUMMARY OF THE INVENTION

The object of the present invention is achieved by the solution provided in the enclosed independent claims. Advantageous implementations of the present invention are further defined in the dependent claims.

According to a first aspect, the invention relates to a system for calibrating a measurement antenna of a radio frequency (RF) test arrangement, comprising a calibration antenna, and a fixture, wherein the calibration antenna is mounted to the fixture, and wherein the fixture comprises an aperture for removably mounting the fixture on the measurement antenna, wherein the calibration antenna is arranged at a fixed distance from the measurement antenna if the fixture is mounted on the measurement antenna. This achieves the advantage that the measurement antenna can be calibrated quickly and accurately.

In particular, the fixture reduces alignment tolerances between the measurement and the calibration antenna. Furthermore, it is easy to align both antennas using the fixture, thus errors during the setup can be prevented.

The measurement antenna and/or the calibration antenna can be RF antennas. Preferably, the antennas are optimized for transmitting and/or receiving RF signals in the 5G frequency range, in particular in the 5G FR2 frequency range above 26 GHz.

In particular, the distance of the calibration antenna from the measurement antenna refers to a distance of a tip of the calibration antenna from a tip of the measurement antenna.

Preferably, the calibration antenna is removably or non-removably mounted to the fixture.

In an embodiment, the fixture comprises a further aperture, wherein the calibration antenna is removably or non-removably mounted in the further aperture. This achieves the advantage that the calibration antenna can be attached at a defined position in the fixture.

In an embodiment, the fixture comprises an elongated element, wherein the aperture and the further aperture are arranged at opposing ends of the elongated element. This achieves the advantage that the measurement antenna and the calibration antenna can be precisely aligned towards each other.

The elongated element can form a base body of the fixture.

In an embodiment, the aperture is designed to positively engage the measurement antenna, in particular a tip or an upper section of the measurement antenna. This achieves the advantage that the measurement antenna can be quickly and accurately mounted in the fixture.

Preferably, the further aperture is designed to positively engage the calibration antenna, in particular a tip or an upper section of the calibration antenna.

The aperture and/or the further aperture can be designed as form-fitting cavities for at least the upper section of the measurement respective calibration antenna. In particular, the fixture can be plugged onto the measurement antenna by means of the aperture. Likewise, the calibration antenna can be plugged into the further aperture.

In an embodiment, if the fixture is mounted on the measurement antenna, a distance between a tip of the calibration antenna and the tip of the measurement antenna is between 2 cm and 8 cm, in particular between 4 cm and 6 cm, more particular approximately 5 cm. This achieves the advantage that both antennas can be aligned at an optimal distance for calibration measurements in the 5G FR2 frequency range above 26 GHz.

In an embodiment, the calibration antenna and the measurement antenna, in particular the tips of both antennas, point towards each other if the fixture is mounted on the measurement antenna. This achieves the advantage that both antennas can be arranged at an optimal alignment angle for calibration measurements.

In an embodiment, the fixture is made of an at least partially RF transparent material, in particular a polymethacrylimide based structural foam. This achieves the advantage that the fixture does not block or attenuate RF calibration signals.

In an embodiment, the calibration antenna is configured to receive an RF signal from the measurement antenna, wherein the system comprises a processing unit configured to determine an antenna transfer function based on the received RF signal, in particular based on characteristics of the received RF signal. This achieves the advantage that the measurement antenna can be calibrated efficiently.

In particular, the antenna transfer function is a transfer function of the measurement antenna. The antenna transfer function can comprise a transmitting antenna transfer function, a receiving antenna transfer function, and/or an antenna system transfer function.

All the above-mentioned embodiments and/or optional features of the system for calibrating the measurement antenna can be combined.

According to a second aspect, the invention relates to a method for calibrating a measurement antenna of a radio frequency (RF) test arrangement, wherein the method comprises the steps of:
providing a calibration antenna, wherein the calibration antenna is mounted to a fixture,
removably mounting the fixture on the measurement antenna by means of an aperture of the fixture, wherein the calibration antenna is arranged at a fixed distance from the measurement antenna if the fixture is mounted on the measurement antenna, and
performing a calibration measurement.

This achieves the advantage that the measurement antenna can be calibrated quickly and accurately.

In particular, the fixture reduces alignment tolerances between the measurement and the calibration antenna. Furthermore, it is easy to align both antennas using the fixture, thus errors during the setup can be prevented.

In an embodiment, the step of performing the calibration measurement comprises:
transmitting an RF signal from the measurement antenna,
receiving said RF signal at the calibration antenna, and
calculating an antenna transfer function based on characteristics of the received RF signal.

This archives the advantage that he measurement antenna can be calibrated efficiently.

Preferably, the calibration antenna is removably or non-removably mounted to the fixture.

In an embodiment, the fixture comprises a further aperture, wherein the calibration antenna is removably or non-removably mounted in the further aperture. This achieves the advantage that the calibration antenna can be attached at a defined position in the fixture.

In an embodiment, the fixture is made of an at least partially RF transparent material, in particular a polymethacrylimide based structural foam. This achieves the advantage that the fixture does not block or attenuate RF calibration signals.

In an embodiment, the measurement antenna is arranged in a test chamber of the RF test arrangement, wherein the method further comprises:
placing the calibration antenna with attached fixture in the test chamber to perform the calibration measurement, and
removing the calibration antenna with attached fixture from the test chamber after the calibration measurement.

In an embodiment, the method comprises the further steps of:
providing a reference antenna,
removably mounting the fixture on the reference antenna by means of the aperture, in particular before mounting the fixture on the measurement antenna,
performing a characterization measurement of the calibration antenna, and
dismounting the fixture from the reference antenna.

This achieves the advantage that characteristics of the calibration antenna can be determined efficiently, thus allowing to more accurately calibrating the measurement antenna, in particular the antenna transfer function based.

In particular, the upper part of the reference antenna has essentially the same shape as the measurement antenna, such that it fits the aperture of the fixture.

All the above-mentioned embodiments and/or optional features of the method for calibrating the measurement antenna can be combined.

The above description with regard to the system for calibrating the measurement antenna according to the present invention is correspondingly valid for the method for calibrating the measurement antenna according to the present invention.

According to a third aspect, the invention relates to a test method for an electronic device, in particular a device under test (DUT), comprising the steps of: placing the electronic device in a test chamber, in particular an anechoic chamber, and performing a test measurement, in particular a radiated power measurement, of the electronic device by means of at least one measurement antenna calibrated according to the method of the second aspect of the invention. This achieves the advantage that the electronic device can be tested efficiently with an accurately calibrated antenna.

Preferably, the at least one measurement antenna is arranged in the test chamber.

The above description with regard to the method for calibrating the measurement antenna according to the present invention is correspondingly valid for the test method for the electronic device according to the present invention.

According to a fourth aspect, the invention relates to an radio frequency (RF) test arrangement, comprising a test chamber, in particular an anechoic chamber, and at least one measurement antenna calibrated according to the method of the second aspect of the invention, wherein the at least one measurement antenna is arranged in the test chamber. This achieves the advantage that the electronic device can be tested efficiently with an accurately calibrated antenna.

In an embodiment, the RF test arrangement comprises a holder configured to hold an electronic device, wherein the holder is arranged in the test chamber. This achieves the advantage that each electronic device that is tested can be arranged at the same fixed position in the chamber.

In particular, this creates repeatable test conditions and avoids variations in the test measurements of different DUTs due to different positions in the chamber.

The above description with regard to the method for calibrating the measurement antenna according to the present invention is correspondingly valid for the RF test arrangement according to the present invention.

### BRIEF DESCRIPTION OF THE DRAWINGS

The invention will be explained in the followings together with the figures.

FIG. 1 shows a schematic diagram of a system for calibrating a measurement antenna of an RF test arrangement according to an embodiment;

FIG. 2 shows a schematic diagram of a fixture according to an embodiment;

FIG. 3 shows a schematic diagram of a setup for characterizing a calibration antenna according to an embodiment;

FIG. 4 shows a schematic diagram of an RF test arrangement according to an embodiment;

FIG. 5 shows a schematic diagram of a method for calibrating a measurement antenna of an RF test arrangement according to an embodiment;

FIG. 6 shows a schematic diagram of a method for performing a calibration measurement according to an embodiment; and

FIG. 7 shows a schematic diagram of a test method for an electronic device according to an embodiment.

### DETAILED DESCRIPTION OF THE PREFERRED EMBODIMENTS

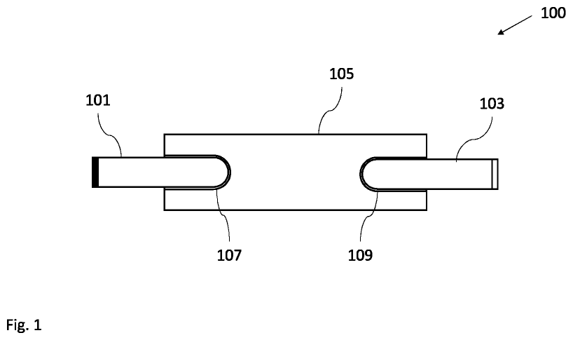

FIG. 1 shows a schematic diagram of a system 100 for calibrating a measurement antenna 101 of an RF test arrangement according to an embodiment.

The system 100 comprises a calibration antenna 103, and a fixture 105, wherein the calibration antenna 103 is mounted to the fixture 105, and wherein the fixture 105 comprises an aperture 107 for removably mounting the fixture 105 on the measurement antenna 101. The calibration antenna 103 is arranged at a fixed distance from the measurement antenna 101 if the fixture 105 is mounted on the measurement antenna 101.

The measurement antenna 101 and/or the calibration antenna 103 can be RF antennas. Preferably, the antennas 101, 103 are optimized for transmitting and/or receiving RF signals in the 5G frequency range, in particular in the 5G FR2 frequency range above 26 GHz.

The fixture 105 in FIG. 1 comprises a further aperture 109, wherein the calibration antenna 103 is mounted in the further aperture 109. The calibration antenna 103 can be mounted removably or non-removably in the further aperture 109. If the calibration antenna 103 is non-removably mounted to the fixture 105, than the calibration antenna 103 and the fixture 105 form a common unit which can be mounted on the measurement antenna.

The aperture 107 and/or the further aperture 109 can each be a mounting aperture, a cavity, a mounting hole or an assembly hole in the fixture.

Preferably, the shape of the aperture 107 corresponds to the shape of an upper section of the measurement antenna 101, such that the fixture 105 can positively engage the measurement antenna, i.e. plugged onto the measurement antenna. This allows quickly and accurately aligning both antennas 101, 103, in particular their distance, by a simple plug connection.

Similarly, the shape of the further aperture 109 corresponds to the shape of an upper section of the calibration antenna 103, such that the calibration antenna 103 can positively engage the further aperture 109, i.e. plugged into the further aperture 109.

The fixture in FIG. 1 comprises an elongated element, wherein the aperture 107 and the further aperture 109 are arranged at opposing ends of the elongated element. The elongated element can be a base body of the fixture 105.

Preferably, the tips of the measurement antenna 101 and the calibration antenna 103 are facing towards each other when the fixture 105 is mounted on the measurement antenna and the calibration antenna 103 is attached to the fixture 105. In particular, this alignment of the antennas 101, 103 is optimal for performing a calibration measurement.

Preferably, the system 100 comprises a processing unit (not shown). The calibration antenna 103 can be configured to receive an RF signal from the measurement antenna. The processing unit can be configured to determine an antenna transfer function of the measurement antenna 101 based on the received RF signal, in particular based on signal characteristics of the received RF signal.

The system 100 can further comprise a vector network analyzer (VNA) for determining the transfer function. The VNA can comprise the processing unit.

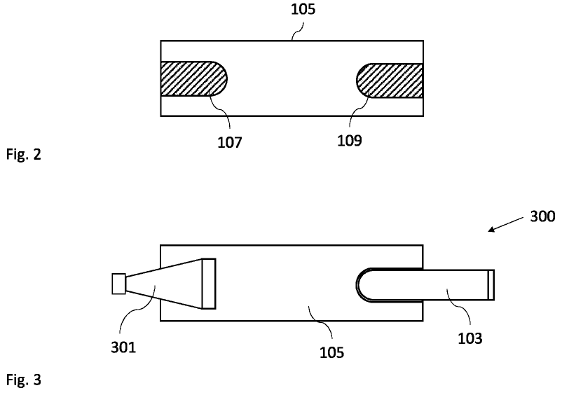

FIG. 2 shows a schematic diagram of the fixture 105 according to an embodiment. In particular, FIG. 2 shows a cross sectional view of the fixture 105.

The fixture 105 shown in FIG. 2 can correspond to the fixture 105 shown in FIG. 1.

The fixture 105 comprises the aperture 107 and the further aperture 109, each aperture 107, 109 forming a cavity for positively engaging the measurement antenna 101 respectively the calibration antenna 103.

The cavities can be designed in such a way that the distances between the tip of each antenna, when inserted into the respective aperture, is between 2 cm and 8 cm, in particular between 4 cm and 6 cm, more particular approximately 5 cm. The distance can be an optimal distance for measurements in the 5G FR2 frequency range, e.g. from 24.25 GHz to 52.6 GHz. In particular, the distance can be a minimum distance for far field measurements in this frequency range.

Preferably, the fixture is made of an RF transparent material to prevent the fixture 105 from attenuating or blocking RF signals that are send between the antennas 101, 103 during calibration.

The fixture 105 can be made of a polymethacrylimide based structural foam, such as Rohacell® or a comparable material. In particular, the foam is lightweight, has a high temperature resistance and a high dynamic strength.

FIG. 3 shows a schematic diagram of a setup 300 for characterizing the calibration antenna 103 according to an embodiment.

The setup 300 comprises a fixture 105, in particular the fixture 105 as shown in FIGS. 1 and 2, and a reference antenna 301. The fixture can be mounted on the reference antenna 301 by means of the aperture 107.

The design of the reference antenna 301, in particular shape and diameter, can be similar to the measurement antenna 101 such that the aperture 107 can engage the reference antenna 301. FIG. 3 shows a symbolic representation of the reference antenna, the actual design of the antenna 301 may differ from this representation.

A characterization measurement of the calibration antenna 103 can be performed using the reference antenna 301. The characterization measurement can comprise a calibration measurement of the calibration antenna 103.

Alternatively, different fixtures can be used for the measurement antenna 101 and the reference antenna 301, in particular if the reference antenna 301 has a different shape or size than the measurement antenna 101.

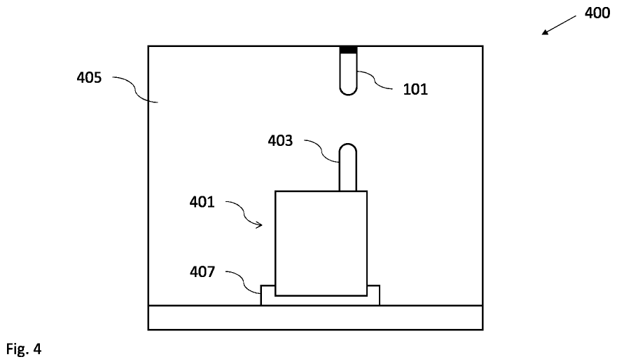

FIG. 4 shows a schematic diagram of an RF test arrangement 400 according to an embodiment.

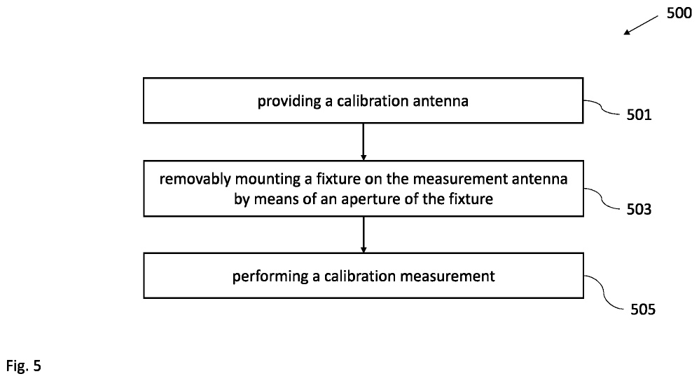

The RF test arrangement 400 comprises a test chamber 405 and at least one measurement antenna 101, wherein the at least one measurement antenna 101 is arranged in the test chamber. In particular, the measurement antenna 101 was calibrated with the system as shown in FIG. 1 above and/or with the method as shown in FIG. 5 below.

The test chamber 405 can be an RF shielded chamber and/or an anechoic chamber.

The RF test arrangement 400 further comprises a holder 407 arranged in the test chamber 405. The holder 407 is configured to hold an electronic device 401, in particular a DUT. The position of the holder 407 in the chamber 405 can be adjustable.

The electronic device 401 can be a measurement device for performing RF measurements, in particular in the 5G frequency range. The electronic device can comprise at least one RF antenna 403 for receiving and/or transmitting RF signals.

The RF test arrangement 400 can comprise a plurality of measurement antennas 101. Preferably, the RF test arrangement 400 comprises one measurement antenna 101 for each RF antenna 403 of the electronic device 401. Each of the measurement antennas 101 can be arranged to point in the direction of one RF antenna 403 of the device 401. In particular, each antenna 101 is adjustably attached to a wall of the test chamber 405.

The electronic device 401 is tested by performing a radiated power measurement using the at least one measurement antenna 101.

For calibrating the measurement antenna 101 in the chamber 405, the electronic device 401 is removed from the chamber 405. Subsequently, the system 100 comprising the fixture 105 and the calibration antenna 103, as shown in FIG. 1, is inserted into the chamber and mounted on the measurement antenna 101. In particular, the aperture 107 of the fixture is plugged onto the measurement antenna 101. After performing the calibration measurement, the system 100 is removed from the chamber 405.

FIG. 5 shows a schematic diagram of a method 500 for calibrating the measurement antenna 101 of the RF test arrangement 400 according to an embodiment.

The method 500 comprises the steps of: providing 501 the calibration antenna 103, wherein the calibration antenna 103 is mounted to the fixture 105; removably mounting 503 the fixture 105 on the measurement antenna 101 by means of the aperture 107 of the fixture 105, wherein the calibration antenna 103 is arranged at a fixed distance from the measurement antenna 101 if the fixture 105 is mounted on the measurement antenna 101; and performing 505 a calibration measurement.

The system 100, as shown in FIG. 1, can be configured to carry out the method 500.

In particular, the fixture 105 comprises the further aperture 109, wherein the calibration antenna 103 is removable or non-removable mounted in the further aperture 109.

In particular, the fixture 105 is made of an at least partially RF transparent material, for instance a polymethacrylimide based structural foam.

Preferably, the measurement antenna 101 is arranged in a test chamber 405 of the RF test arrangement 400, in particular the test chamber 405 as shown in FIG. 4. The method 500 can further comprise the steps of:
placing the calibration antenna 103 with attached fixture 105 in the test chamber to perform the calibration measurement; and
removing the calibration antenna 103 with attached fixture 105 from the test chamber 405 after the calibration measurement.

While performing the calibration measurement with the calibration antenna 103 and fixture 105 in the test chamber 405, the distance, orientation and tilt angle between the measurement antenna 101 and the calibration antenna 103 are aligned so that the measurement antenna 101 points at the calibration antenna and the distance between both antennas 101, 103 is fixed. Thereby, the tip of the calibration antenna 105 is arranged approximately at the same position in the test chamber 405 at which a tip of the RF antenna 403 of the electronic device 401 is arranged during testing of the device 401.

The method 500 can further comprise a characterization of the calibration antenna 103 with a reference antenna 301 as shown in FIG. 3. Therefore, the method 500 can comprise the further steps of:
providing the reference antenna 301;
removably mounting the fixture 105 on the reference antenna 301 by means of the aperture 107, in particular before mounting the fixture 105 on the measurement antenna 101;
performing a characterization measurement of the calibration antenna 103; and
dismounting the fixture 105 from the reference antenna 301.

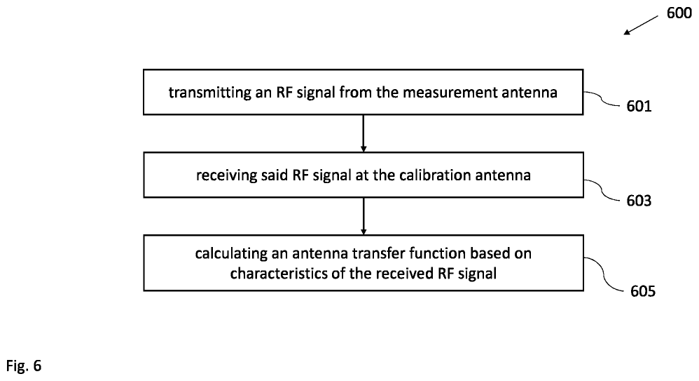

FIG. 6 shows a schematic diagram of a method 600 for performing the calibration measurement according to an embodiment.

In particular, the method 600 as shown in FIG. 6 corresponds to the method step 505 of the method 500 for calibrating the measurement antenna 101, as shown in FIG. 5, and comprises sub-steps of said method step 505.

The method 600 comprises: transmitting 601 an RF signal from the measurement antenna 101; receiving 603 said RF signal at the calibration antenna 103; and calculating 605 an antenna transfer function based on characteristics of the received RF signal. In particular, the antenna transfer function is a S21 transfer function between the measurement antenna 101 and the calibration antenna 103.

The methods 500, 600 can be performed on each measurement antenna 101 of the RF test arrangement 400. In this way, path losses and variations between the different measurement antennas 101 of the test arrangement 400, e.g. caused by production differences of the antennas 101, can be determined.

In this way, reflection and/or transmission characteristics such as S-parameters, in particular S21, can be calculated for each measurement antenna 101.

In particular, the gain of each measurement antenna 101 is known.

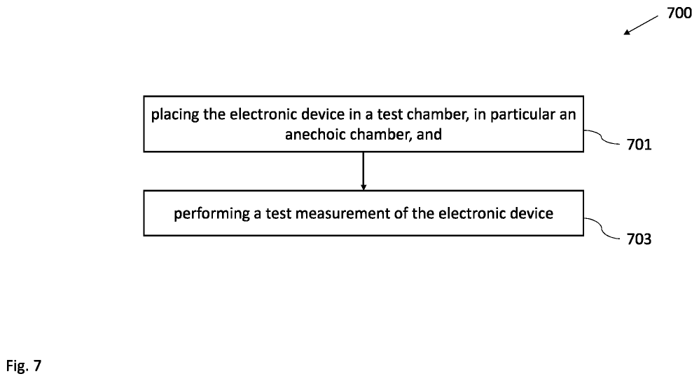

FIG. 7 shows a schematic diagram of a test method 700 for the electronic device 401 according to an embodiment.

The test method 700 comprises: placing 701 the electronic device 401 in the test chamber 405, in particular the test chamber 405 as shown in FIG. 4; and performing 703 a test measurement, in particular a radiated power measurement, of the electronic device 401. In particular, at least one measurement antenna 101 calibrated with the system 100, as shown in FIG. 1, and/or with the method 500, as shown in FIG. 5, is used to perform the test measurement.

The test method 700 can be carried out in the RF test arrangement 400.

All features of all embodiments described, shown and/or claimed herein can be combined with each other.

1. A system for calibrating a measurement antenna of an RF test arrangement, comprising:
a calibration antenna, and
a fixture,
wherein the calibration antenna is mounted to the fixture, and
wherein the fixture comprises an aperture for removably mounting the fixture on the measurement antenna,
wherein the calibration antenna is arranged at a fixed distance from the measurement antenna if the fixture is mounted on the measurement antenna.

2. The system according to claim 1, wherein the fixture comprises a further aperture, wherein the calibration antenna is removable or non-removable mounted in the further aperture.

3. The system according to claim 2, wherein the fixture comprises an elongated element, wherein the aperture and the further aperture are arranged at opposing ends of the elongated element.

4. The system according to claim 1, wherein the aperture is designed to positively engage the measurement antenna, in particular a tip or an upper section of the measurement antenna.

5. The system according to claim 1, wherein, if the fixture is mounted on the measurement antenna, a distance between a tip of the calibration antenna and the tip of the measurement antenna is between 2 cm and 8 cm, in particular between 4 cm and 6 cm, more particular approximately 5 cm.

6. The system according to claim 1, wherein the calibration antenna and the measurement antenna point towards each other if the fixture is mounted on the measurement antenna.

7. The system according to claim 1, wherein the fixture is made of an at least partially RF transparent material, in particular a polymethacrylimide based structural foam.

8. The system according to claim 1, wherein the calibration antenna is configured to receive an RF signal from the measurement antenna, wherein the system comprises a processing unit configured to determine an antenna transfer function based on the received RF signal.

9. A method for calibrating a measurement antenna of an RF test arrangement, wherein the method comprises the steps of:
providing a calibration antenna, wherein the calibration antenna is mounted to a fixture;
removably mounting the fixture on the measurement antenna by means of an aperture of the fixture, wherein the calibration antenna is arranged at a fixed distance from the measurement antenna if the fixture is mounted on the measurement antenna; and
performing a calibration measurement.

10. The method according to claim 9, wherein the step of performing the calibration measurement comprises:
transmitting an RF signal from the measurement antenna;
receiving said RF signal at the calibration antenna; and
calculating an antenna transfer function based on characteristics of the received RF signal.

11. The method according to claim 9, wherein the fixture comprises a further aperture, wherein the calibration antenna is removable or non-removable mounted in the further aperture.

12. The method according to claim 9, wherein the fixture is made of an at least partially RF transparent material, in particular a polymethacrylimide based structural foam.

13. The method according to claim 9, wherein the measurement antenna is arranged in a test chamber of the RF test arrangement, wherein the method further comprises:
placing the calibration antenna with attached fixture in the test chamber to perform the calibration measurement; and
removing the calibration antenna with attached fixture from the test chamber after the calibration measurement.

14. The method according to claim 9, further comprising:
providing a reference antenna;
removably mounting the fixture on the reference antenna by means of the aperture, in particular before mounting the fixture on the measurement antenna;
performing a characterization measurement of the calibration antenna; and
dismounting the fixture from the reference antenna.

15. A test method for an electronic device, in particular a DUT, comprising the steps of:
placing the electronic device in a test chamber, in particular an anechoic chamber; and
performing a test measurement, in particular a radiated power measurement, of the electronic device by means of at least one measurement antenna calibrated according to the method of claim 9.

16. An RF test arrangement, comprising a test chamber, in particular an anechoic chamber, and at least one measurement antenna calibrated according to the method of claim 9, wherein the at least one measurement antenna is arranged in the test chamber.

17. The RF test arrangement according to claim 16, comprising a holder configured to hold an electronic device, wherein the holder is arranged in the test chamber.
